(19) United States
(12) Patent Application Publication
(10) Pub. No.: US 2025/0095991 A1
(43) Pub. Date: Mar. 20, 2025

(54) ETCHING METHOD AND PLASMA PROCESSING APPARATUS

(71) Applicant: Tokyo Electron Limited, Tokyo (JP)

(72) Inventors: Koki MUKAIYAMA, Miyagi (JP); Takayuki KATSUNUMA, Miyagi (JP)

(73) Assignee: Tokyo Electron Limited, Tokyo (JP)

(21) Appl. No.: 18/966,174

(22) Filed: Dec. 3, 2024

Related U.S. Application Data
(63) Continuation of application No. PCT/JP2023/021305, filed on Jun. 8, 2023.
(60) Provisional application No. 63/351,023, filed on Jun. 10, 2022.

(51) Int. Cl. H01L 21/033; H01J 37/32; H01L 21/311

(52) U.S. Cl. CPC H01L 21/0337; H01J 37/32449; H01J 37/32522; H01L 21/31116; H01L 21/31144; H01J 2237/334

(57) ABSTRACT

Provided is a technique for improving a mask selectivity in etching. An etching method according to the present disclosure includes step (a) preparing a substrate including a silicon-containing film and a mask on the silicon-containing film, the mask including an opening pattern, step (b) forming a metal-containing film on the mask, and step (c) etching the silicon-containing film by generating the plasma from a first processing gas containing a hydrogen fluoride gas.

### CROSS-REFERENCE TO RELATED APPLICATIONS

This application is a bypass continuation application of international application No. PCT/JP2023/021305 having an international filing date of Jun. 8, 2023, and designating the United States, the international application being based upon and claiming the benefit of priority from U.S. Application No. 63/351,023, filed on Jun. 10, 2022, the entire contents of each are incorporated herein by reference.

### TECHNICAL FIELD

Exemplary embodiments of the present disclosure relate to an etching method and a plasma processing apparatus.

### BACKGROUND

JP2016-39310A discloses a method for etching a multilayer film.

### CITATION LIST

### Patent Documents

Patent Document 1: JP2016-39310A

### SUMMARY

The present disclosure provides a technique for improving a mask selectivity in etching.

In one exemplary embodiment of the present disclosure, there is provided an etching method including (a) preparing a substrate including a silicon-containing film and a mask on the silicon-containing film, the mask including an opening pattern, (b) forming a metal-containing film on the mask, and (c) etching the silicon-containing film by generating the plasma from a first processing gas containing a hydrogen fluoride gas.

According to one exemplary embodiment of the present disclosure, a technique for improving a mask selectivity in etching may be provided.

### BRIEF DESCRIPTION OF DRAWINGS

FIG. 1 is a view illustrating a configuration example of a plasma processing system.

FIG. 2 is a view illustrating a configuration example of a capacitively-coupled plasma processing apparatus.

FIG. 3 is a view illustrating an example of a selectivity and bowing.

FIG. 4 is a flowchart illustrating an example of an etching method according to an exemplary embodiment of the present disclosure.

FIG. 5 is a view illustrating an example of a cross-sectional structure of a substrate W prepared in Step ST1.

FIG. 6 is a view illustrating an example of a cross-sectional structure of the substrate W after processing in Step ST2.

FIG. 7 is a view illustrating an example of a cross-sectional structure of the substrate W after processing in Step ST3.

FIG. 8 is a view illustrating an example of a chiller.

FIG. 9 is a table illustrating experimental conditions and experimental results of Experiment 1.

FIG. 10 is a table illustrating experimental conditions and experimental results of Experiment 2.

FIG. 11 is a view illustrating experimental results of Experiment 3.

### DETAILED DESCRIPTION

Hereinafter, embodiments of the present disclosure will be described.

In an exemplary embodiment, an etching method is provided. The etching method includes: (a) preparing a substrate including a silicon-containing film and a mask on the silicon-containing film, the mask including an opening pattern, (b) forming a metal-containing film on the mask, and (c) etching the silicon-containing film by generating the plasma from a first processing gas containing a hydrogen fluoride gas.

In one exemplary embodiment, the silicon-containing film may include a silicon oxide film, a silicon nitride film, a polysilicon film, or a laminated film including two or more types thereof.

In one exemplary embodiment, the mask may include a silicon-containing film different from the silicon-containing film, or a carbon-containing film or a metal-containing film.

In one exemplary embodiment, the mask may include an amorphous carbon film or a spin-on carbon film.

In one exemplary embodiment, the mask may include a film including at least one type of metal selected from the group including tungsten, molybdenum, titanium, and ruthenium, or an oxide film, a nitride film, or a carbon film including at least one type of metal.

In one exemplary embodiment, the (b) may include forming the metal-containing film from a second processing gas containing the metal-containing gas.

In one exemplary embodiment, the metal-containing gas may include at least one type of metal selected from the group including tungsten, molybdenum, titanium, and ruthenium.

In one exemplary embodiment, the metal-containing gas may include tungsten hexafluoride or molybdenum hexafluoride.

In one exemplary embodiment, the (b) may include forming the metal-containing film by generating the plasma from the second processing gas.

In one exemplary embodiment, the (b) may include forming the metal-containing film by causing the mask to adsorb a metal-containing precursor.

In one exemplary embodiment, the (b) may include forming the metal-containing film by generating the plasma from a gas that oxidizes or reduces at least a portion of the metal-containing precursor adsorbed by the mask.

In one exemplary embodiment, in the (b), a portion of the metal-containing precursor adsorbed by the mask does not need to be oxidized or reduced.

In one exemplary embodiment, the (b) may include forming the metal-containing film by physical vapor deposition.

In one exemplary embodiment, the (a) may include disposing the substrate on the substrate support, and the (b) may include forming the metal-containing film by sputtering a metal-containing electrode disposed to face the substrate support.

In one exemplary embodiment, in the etching method, the first processing gas may further include a phosphorus-containing gas.

In one exemplary embodiment, the phosphorus-containing gas may include phosphorus halide or phosphorus chloride.

In one exemplary embodiment, the first processing gas may include a carbon-containing gas.

In one exemplary embodiment, the first processing gas may further include a halogen-containing gas.

In one exemplary embodiment, the first processing gas may include at least one type of gas selected from the group including an oxygen-containing gas, a boron-containing gas, and a metal-containing gas.

In one exemplary embodiment, a flow rate of the hydrogen fluoride gas is highest in the first processing gas.

In one exemplary embodiment, in the (b), a temperature of the substrate support that supports the substrate is set to a first temperature, and in the (c), the temperature of the substrate support is set to a second temperature lower than the first temperature.

In one exemplary embodiment, the first temperature may be 0° C. or higher, and the second temperature is lower than 0° C.

In one exemplary embodiment, in the etching method, a cycle including the (b) and the (c) is repeated multiple times.

In an exemplary embodiment, an etching method is provided. The etching method includes (a) preparing the substrate including the silicon-containing film and the mask on the silicon-containing film, the mask including the opening pattern, (b) forming the metal-containing film on the mask, and (c) etching the silicon-containing film by generating the plasma from the first processing gas.

In one exemplary embodiment, the first processing gas includes one or more gases from which plasma including a hydrogen fluoride species is generated when the plasma is generated from the first processing gas.

In one exemplary embodiment, there is provided a plasma processing apparatus including a chamber and a controller. The plasma processing apparatus is configured such that the controller performs (a) a control for preparing a substrate including a silicon-containing film and a mask on the silicon-containing film inside a chamber, the mask including an opening pattern, (b) a control for forming a metal-containing film on the mask, and (c) a control for etching the silicon-containing film by generating plasma from a first processing gas containing a hydrogen fluoride gas.

Hereinafter, each embodiment of the present disclosure will be described in detail with reference to the drawings. In the drawings, the same or similar elements are denoted by the same reference numerals, and overlapping descriptions thereof will be omitted. Unless otherwise specified, a positional relationship of up/down, left/right, or the like will be described based on a positional relationship illustrated in the drawings. The dimensional ratios in the drawings do not indicate actual ratios, and the actual ratios are not limited to the illustrated ratios.

### Configuration Example of Plasma Processing System

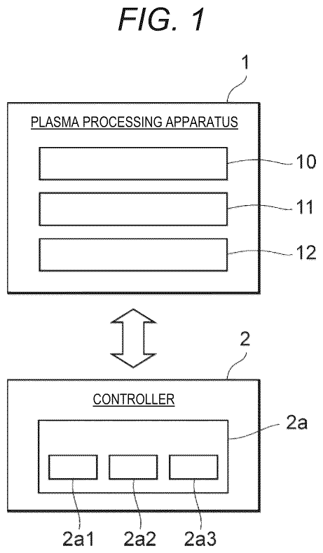

FIG. 1 is a diagram for explaining an example of a configuration of a plasma processing system. In an embodiment, a plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. Further, the plasma processing chamber 10 has at least one gas supply port for supplying at least one processing gas into the plasma processing space, and at least one gas exhaust port for exhausting the gas from the plasma processing space. The gas supply port is connected to a gas supply 20 which will be described later, and the gas exhaust port is connected to an exhaust system 40 which will be described later. The substrate support 11 is disposed in the plasma processing space and has a substrate support surface for supporting the substrate.

The plasma generator 12 is configured to generate plasma from at least one processing gas supplied into the plasma processing space. The plasma formed in the plasma processing space may be Capacitively Coupled Plasma (CCP), Inductively Coupled Plasma (ICP), Electron-Cyclotron-Resonance Plasma (ECR plasma), Helicon Wave Plasma (HWP), Surface Wave Plasma (SWP), or the like. Further, various types of plasma generators, including an alternating current (AC) plasma generator and a direct current (DC) plasma generator, may be used. In one embodiment, an AC signal (AC power) used by the AC plasma generator has a frequency in a range of 100 kHz to 10 GHz. Accordingly, the AC signal includes a radio frequency (RF) signal and a microwave signal. In one embodiment, the RF signal has a frequency in a range of 100 kHz to 150 MHz.

The controller 2 processes computer-executable instructions for instructing the plasma processing apparatus 1 to execute various steps described herein below. The controller 2 may be configured to control the respective components of the plasma processing apparatus 1 to execute the various steps described herein below. In an embodiment, part or all of the controller 2 may be included in the plasma processing apparatus 1. The controller 2 may include a processor 2al, a storage unit 2a2, and a communication interface 2a3. The controller 2 is implemented by, for example, a computer 2a. The processor 2al may be configured to read a program from the storage unit 2a2 and perform various control operations by executing the read program. The program may be stored in advance in the storage unit 2a2, or may be acquired via a medium when necessary. The acquired program is stored in the storage unit 2a2, and is read from the storage unit 2a2 and executed by the processor 2al. The medium may be various storing media readable by the computer 2a, or may be a communication line connected to the communication interface 2a3. The processor 2al may be a Central Processing Unit (CPU). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. The storage unit 2a2 may include a random access memory (RAM), a read only memory (ROM), a hard disk drive (HDD), a solid state drive (SSD), or a combination thereof. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC. The communication interface 2a3 may communicate with the plasma processing apparatus 1 via a communication line such as a local area network (LAN).

### <Configuration Example of Capacitively-Coupled Plasma Processing Apparatus>

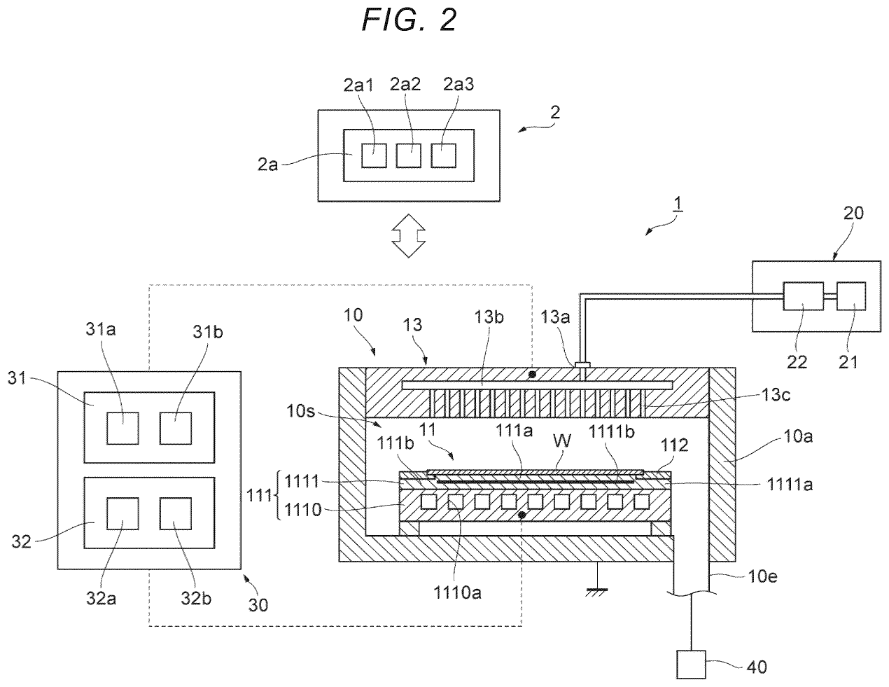

Hereinafter, a configuration example of a capacitively-coupled plasma processing apparatus as an example of the plasma processing apparatus 1 will be described. FIG. 2 is a view for explaining an example of a configuration of a capacitively-coupled plasma processing apparatus.

The capacitively-coupled plasma processing apparatus 1 includes the plasma processing chamber 10, the gas supply 20, a power source 30, and the exhaust system 40. Further, the plasma processing apparatus 1 includes a substrate support 11 and a gas introduction unit (i.e., gas introducer). The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one embodiment, the shower head 13 constitutes at least a part of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 has a central region 111a for supporting a substrate W and an annular region 111b for supporting the ring assembly 112. A wafer is an example of the substrate W. The annular region 111b of the main body 111 surrounds the central region 111a of the main body 111 in a plan view. The substrate W is disposed on the central region 111a of the main body 111 and the ring assembly 112 is disposed on the annular region 111b of the main body 111 to surround the substrate W on the central region 111a of the main body 111. Accordingly, the central region 111a is also referred to as a substrate support surface for supporting the substrate W, and the annular region 111b is also referred to as a ring support surface for supporting the ring assembly 112.

In one embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In one embodiment, the ceramic member 1111a also has the annular region 111b. Other members that surround the electrostatic chuck 1111, such as an annular electrostatic chuck and an annular insulating member, may have the annular region 111b. In this case, the ring assembly 112 may be disposed on the annular electrostatic chuck or the annular insulating member, or may be disposed on both the electrostatic chuck 1111 and the annular insulating member. Further, at least one RF/DC electrode coupled to the RF power source 31 and/or the DC power source 32 to be described later may be disposed in the ceramic member 1111a. In this case, at least one RF/DC electrode functions as the lower electrode. In a case where the bias RF signal and/or the DC signal to be described later are supplied to at least one RF/DC electrode, the RF/DC electrode is also referred to as a bias electrode. The conductive member of the base 1110 and at least one RF/DC electrode may function as a plurality of lower electrodes. Further, the electrostatic electrode 1111b may function as the lower electrode. Accordingly, the substrate support 11 includes at least one lower electrode.

The ring assembly 112 includes one or more annular members. In one embodiment, one or more annular members include one or more edge rings and at least one cover ring. The edge ring is formed of a conductive material or an insulating material, and the cover ring is formed of an insulating material.

Further, the substrate support 11 may include a temperature control module (i.e., temperature controller) configured to adjust at least one of the electrostatic chuck 1111, the ring assembly 112, and the substrate to a target temperature. The temperature control module may include a heater, a heat transfer medium, a flow path 1110a, or a combination thereof. A heat transfer fluid, such as brine or gas, flows through the flow path 1110a. In one embodiment, the flow path 1110a is formed inside the base 1110, and one or more heaters are disposed in the ceramic member 1111a of the electrostatic chuck 1111. Further, the substrate support 11 may include a heat transfer gas supply configured to supply a heat transfer gas to a gap between a rear surface of the substrate W and the central region 111a.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. Further, the shower head 13 includes at least one upper electrode. The gas introduction unit may include, in addition to the shower head 13, one or a plurality of side gas injectors (SGI) that are attached to one or a plurality of openings formed in the sidewall 10a.

The gas supply 20 may include at least one gas source 21 and at least one flow rate controller 22. In one embodiment, the gas supply 20 is configured to supply at least one processing gas from the respective corresponding gas sources 21 to the shower head 13 via the respective corresponding flow rate controllers 22. Each flow rate controller 22 may include, for example, a mass flow controller or a pressure-controlled flow rate controller. Further, the gas supply 20 may include at least one flow rate modulation device that modulates or pulses the flow rate of at least one processing gas.

The power source 30 includes an RF power source 31 coupled to plasma processing chamber 10 via at least one impedance matching circuit. The RF power source 31 is configured to supply at least one RF signal (RF power) to at least one lower electrode and/or at least one upper electrode. As a result, plasma is formed from at least one processing gas supplied into the plasma processing space 10s. Accordingly, the RF power source 31 may function as at least a part of the plasma generator 12. Further, supplying the bias RF signal to at least one lower electrode can generate a bias potential in the substrate W to attract an ionic component in the formed plasma to the substrate W.

In one embodiment, the RF power source 31 includes a first RF generator 31a and a second RF generator 31b. The first RF generator 31a is configured to be coupled to at least one lower electrode and/or at least one upper electrode via at least one impedance matching circuit to generate a source RF signal (source RF power) for plasma generation. In one embodiment, the source RF signal has a frequency in the range of 10 MHz to 150 MHz. In one embodiment, the first RF generator 31a may be configured to generate a plurality of source RF signals having different frequencies. The generated one or more source RF signals are supplied to at least one lower electrode and/or at least one upper electrode.

The second RF generator 31b is configured to be coupled to at least one lower electrode via at least one impedance matching circuit to generate the bias RF signal (bias RF power). A frequency of the bias RF signal may be the same as or different from a frequency of the source RF signal. In one embodiment, the bias RF signal has a lower frequency than the frequency of the source RF signal. In one embodiment, the bias RF signal has a frequency in the range of 100 kHz to 60 MHz. In one embodiment, the second RF generator 31b may be configured to generate a plurality of bias RF signals having different frequencies. The generated one or more bias RF signals are supplied to at least one lower electrode. Further, in various embodiments, at least one of the source RF signal and the bias RF signal may be pulsed.

Further, the power source 30 may include a DC power source 32 coupled to the plasma processing chamber 10. The DC power source 32 includes a first DC generator 32a and a second DC generator 32b. In one embodiment, the first DC generator 32a is configured to be connected to at least one lower electrode to generate the first DC signal. The generated first DC signal is applied to at least one lower electrode. In one embodiment, the second DC generator 32b is configured to be connected to at least one upper electrode to generate a second DC signal. The generated second DC signal is applied to at least one upper electrode.

In various embodiments, the first and second DC signals may be pulsed. In this case, the sequence of voltage pulses is applied to at least one lower electrode and/or at least one upper electrode. The voltage pulse may have a pulse waveform of a rectangle, a trapezoid, a triangle or a combination thereof. In one embodiment, a waveform generator for generating a sequence of voltage pulses from the DC signal is connected between the first DC generator 32a and at least one lower electrode. Accordingly, the first DC generator 32a and the waveform generator configure a voltage pulse generator. In a case where the second DC generator 32b and the waveform generator configure the voltage pulse generator, the voltage pulse generator is connected to at least one upper electrode. The voltage pulse may have a positive polarity or a negative polarity. Further, the sequence of the voltage pulses may include one or more positive voltage pulses and one or more negative voltage pulses in one cycle. The first and second DC generators 32a and 32b may be provided in addition to the RF power source 31, and the first DC generator 32a may be provided instead of the second RF generator 31b.

The exhaust system 40 may be connected to, for example, a gas exhaust port 10e disposed at a bottom portion of the plasma processing chamber 10. The exhaust system 40 may include a pressure adjusting valve and a vacuum pump. The pressure in the plasma processing space 10s is adjusted by the pressure adjusting valve. The vacuum pump may include a turbo molecular pump, a dry pump, or a combination thereof.

### <Example of Substrate State Before and After Plasma Etching>

One of indicators for evaluating the plasma etching is a selectivity between the mask and the etching target film. As an example, the selectivity can be expressed by a ratio of an etching rate of the etching target film to an etching rate of the mask when the etching target film is etched via the mask.

Further, bowing is known as one of shape abnormalities in plasma etching. The bowing is a phenomenon in which an opening dimension of a portion of a sidewall of a recess formed by etching becomes larger than an opening dimension of a top portion of the recess. For example, the portion where the bowing occurs has a barrel shape in a cross-sectional view. It is conceivable that the bowing may occur when a portion of the sidewall of the recess is scraped by ions or the like which are bounced by the mask or the like.

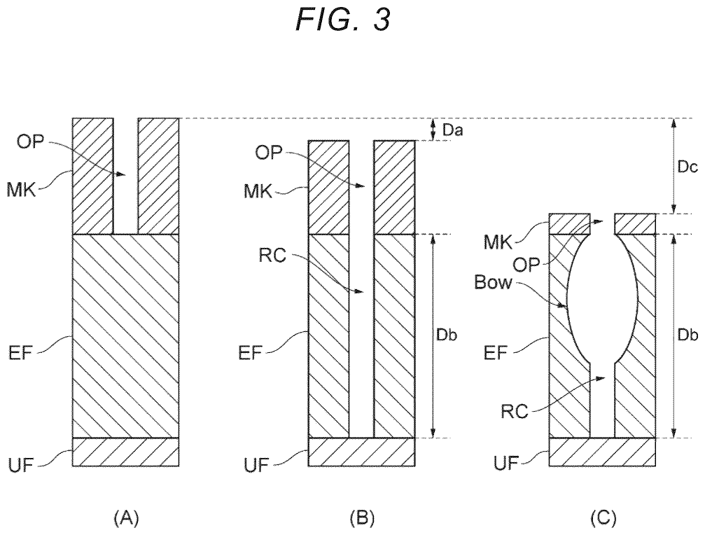

FIG. 3 is a view illustrating an example of the selectivity and the bowing. (A) of FIG. 3 is a view illustrating an example of a cross-sectional structure of the substrate in a state where a mask MK including an opening OP is formed on an etching target film EF. (B) of FIG. 3 is a view illustrating an example of the cross-sectional structure of the substrate in a state where the etching target film EF is etched under a certain condition via the opening OP of the mask MK. (C) of FIG. 3 is a view illustrating an example of the cross-sectional structure of the substrate in a state where the etching target film EF is etched under other conditions via the opening OP of the mask MK.

In (B) of FIG. 3, the selectivity may be represented by Db/Da, that is, an etching amount (or an etching rate) of the etching target film EF with respect to an etching amount (or an etching rate) of the mask MK. In (C) of FIG. 3, the selectivity may be represented by Db/Dc, that is, the etching amount (or the etching rate) of the etching target film EF with respect to the etching amount (or the etching rate) of the mask MK. The selectivity in (B) of FIG. 3 is higher than the selectivity in (C) of FIG. 3. The selectivity may vary depending on a material of the mask MK, a material of the etching target film EF, etching conditions, and the like.

In an example in (C) of FIG. 3, a barrel-shaped bowing Bow in a cross-sectional view occurs on an upper portion side (low aspect region) of a recess RC. The opening dimension of the recess RC in which the bowing Bow occurs is larger than the opening dimension of a middle portion side to a lower portion side (a middle aspect region to a high aspect region) of the recess RC. In some cases, the bowing may occur not only on the upper portion side of the recess RC but also on the middle portion to the lower portion side of the recess RC.

An etching method according to an exemplary embodiment of the present disclosure (hereinafter, also referred to as the “present method”) may improve a selectivity in etching. Further, the present method can suppress the bowing in the etching. Hereinafter, the method will be described with reference to the drawings.

### <Example of Present Method>

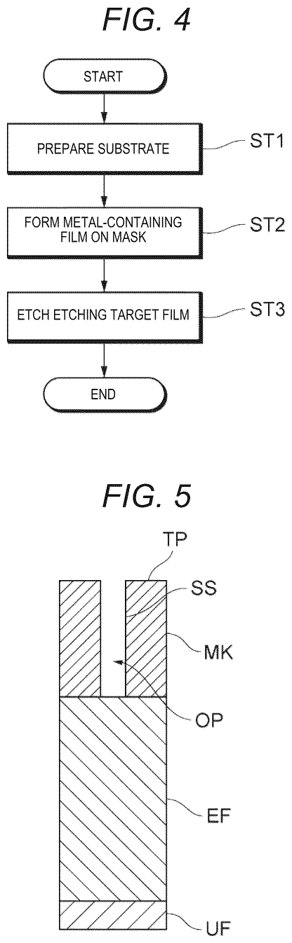

FIG. 4 is a flowchart illustrating an example of the present method. The present method includes Step ST1 of preparing the substrate, Step ST2 of forming the metal-containing film on the mask, and Step ST3 of etching the etching target film. In one embodiment, processing in each step may be performed in the plasma processing apparatus 1 (refer to FIGS. 1 and 2). In the following example, the controller 2 controls each component of the capacitively-coupled plasma processing apparatus 1 (refer to FIG. 2) to perform the present method.

### (Step ST1: Preparation of Substrate)

In Step ST1, the substrate is prepared. In Step ST1, the substrate W is disposed in the central region 111a of the substrate support 11, and is held on the substrate support 11 by the electrostatic chuck 1111. FIG. 5 is a view illustrating an example of a cross-sectional structure of the substrate W prepared in Step ST1. As illustrated in FIG. 5, the substrate W includes an etching target film EF and a mask MK disposed on the etching target film EF. In one embodiment, the etching target film EF may be formed on an underlying film UF. The substrate W may be used for manufacturing a semiconductor device. The semiconductor device includes, for example, a semiconductor memory device, such as a DRAM or a 3D-NAND flash memory.

In one embodiment, the underlying film UF is a silicon wafer, an organic film formed on the silicon wafer, a dielectric film, a metal film, a semiconductor film, or the like. In one embodiment, the underlying film UF may include an etching stop film. In one embodiment, the etching stop film includes at least one type of metal selected from the group including tungsten, molybdenum, ruthenium, titanium, indium, gallium, and zinc. The etching stop film may include, for example, carbide or silicide of the metal. The etching stop film may be, for example, a tungsten-containing film. The etching stop film may further include tungsten and at least one type selected from the group including silicon, carbon, and nitrogen. In an example, the etching stop film includes at least one type selected from the group including tungsten carbide, tungsten silicide, WSiN, and WSiC. The etching stop film may include, for example, at least one selected from the group including ruthenium, tungsten silicide, titanium nitride, molybdenum, and InGaZnO.

In one embodiment, the underlying film UF may be configured by laminating a plurality of films. In a case where the underlying film UF includes the plurality of films, the etching stop film may be formed on an uppermost layer of the underlying film UF. That is, the etching stop film may be disposed to be in contact with the etching target film EF.

The etching target film EF is a film serving as a target to be etched by using the present method. The etching target film EF may include one film, or may be configured by laminating the plurality of films.

In one embodiment, the etching target film EF is a silicon-containing film. The silicon-containing film may be a silicon oxide film, a silicon nitride film, a silicon oxynitride film, a silicon carbonitride film, a polycrystalline silicon film, or a carbon-containing silicon film. The silicon-containing film may be configured by laminating the plurality of films. For example, the silicon-containing film may be configured by alternately laminating the silicon oxide film and the silicon nitride film. For example, the silicon-containing film may be configured by alternately laminating the silicon oxide film and the polycrystalline silicon film. For example, the silicon-containing film may be a laminated film including the silicon nitride film, the silicon oxide film, and the polycrystalline silicon film. For example, the silicon-containing film may be configured by laminating the silicon oxide film and the silicon carbonitride film. For example, the silicon-containing film may be a laminated film including a silicon oxide film, a silicon nitride film, and a silicon carbonitride film. The silicon-containing film may be the silicon-containing film doped with phosphorus, boron, nitrogen, or the like.

The mask MK has a pattern that is transferred to the etching target film EF by etching. The mask MK may be a monolayer mask having one layer, or may be a multilayer mask having two or more layers. As illustrated in FIG. 5, a sidewall SS of the mask MK defines at least one opening OP on the etching target film EF. The opening OP is a space on the etching target film EF, and is surrounded by the sidewall SS of the mask MK. That is, an upper surface of the etching target film EF includes a region covered with the mask MK and a region exposed in a bottom portion of the opening OP.

The opening OP may have any shape in a plan view of the substrate W, that is, when the substrate W is viewed in a downward direction from above in FIG. 5. The shape may be, for example, a circle, an ellipse, a rectangle, a line, or a shape obtained by combining one or more types thereof. The mask MK may include a plurality of sidewalls, and the plurality of sidewalls may define a plurality of the openings OP. The plurality of openings OP may each have a linear shape, and may be arranged at regular intervals to form a line and space pattern. Further, the plurality of openings OP may each have a hole shape and may form an array pattern. In an example, an aspect ratio (e.g., ratio of the depth to the width of the opening OP) of the mask MK may be 20 or higher, 30 or higher, and 40 or higher.

The mask MK may be appropriately selected depending on the etching target film EF. In one embodiment, the mask MK is formed of a material whose etching rate with respect to the plasma formed in Step ST2 or Step ST3 is lower than the etching target film EF.

In one embodiment, the mask MK is a carbon-containing mask, a silicon-containing mask, or a metal-containing mask. In an example, the carbon-containing mask is an amorphous carbon (ACL) film, a spin-on carbon (SOC) film, or a photoresist film. The ACL film may be doped with an element such as boron, arsenic, tungsten, or xenon.

In a case where the mask MK is the silicon-containing mask and the etching target film EF is the silicon-containing film, the mask MK may be the silicon-containing film different from the etching target film EF. As an example, in a case where the etching target film EF is a laminated film of the silicon oxide film and the silicon nitride film, the mask MK may be the polysilicon film.

The metal-containing mask may be the metal-containing film including tungsten (W), molybdenum (Mo), titanium (Ti), or the like.

Each of the underlying film UF, the etching target film EF, and the mask MK may be formed by using any method. For example, the underlying film UF, the etching target film EF, and the mask MK may be formed by using a CVD method, an ALD method, a PVD method, a spin coating method, or the like. For example, the mask MK may be formed by using lithography. Further, the opening OP of the mask MK may be formed by etching the mask MK. Each of the underlying film UF, the etching target film EF, and the mask MK may be a flat film, or may be a film having irregularities. The substrate W may be further provided with another film below the underlying film UF. In this case, a recess having a shape corresponding to the opening OP may be formed in the etching target film EF and the underlying film UF, and the recess may be used as a mask for etching the other film.

At least a portion of a process of forming the underlying film UF, the etching target film EF, and the mask MK of the substrate W may be performed in the plasma processing space 10s as a part of Step ST1. For example, in a case where the opening OP of the mask MK is formed by etching, the etching in Step ST1 and the etching in Step ST2 may be consecutively performed in the plasma processing space 10s. That is, the etching of the mask MK can be performed partially in Step ST1 and partially in Step ST2. In one embodiment, the substrate W may be provided in the plasma processing space 10s after the substrate W is entirely or partially formed by an apparatus or a chamber outside the plasma processing apparatus 1.

In one embodiment, after the substrate W is provided in the central region 111a of the substrate support 11, the substrate support 11 is controlled to a given temperature by a temperature control module. In an example, controlling the temperature of the substrate support 11 to the given temperature includes setting the temperature of a heat transfer fluid flowing through the flow path 1110a or a heater temperature to a given temperature, or setting the temperature to a temperature different from the given temperature. The time at which the heat transfer fluid starts to flow through the flow path 1110a may be before or after the substrate W is placed on the substrate support 11, or may be at the same time. Further, the temperature of the substrate support 11 may be controlled to the given temperature before Step ST1.

In one embodiment, instead of controlling the substrate support 11 to the given temperature, the substrate W may be controlled to the given temperature. Controlling the temperature of the substrate W to the given temperature includes setting the temperature of the heat transfer fluid flowing through the substrate support 11 and the flow path 1110a and/or the heater temperature to the given temperature, or setting the temperature to the temperature different from the given temperature.

### (Step ST2: Formation of Metal-Containing Film)

In Step ST2, the metal-containing film is formed on the mask MK. The metal-containing film MF may be formed on an upper surface TP and/or a side surface SS of the mask MK. The thickness of the metal-containing film MF formed on the side surface SS of the mask MK may be 10 nm or smaller, or 5 nm or smaller, for example. The thickness of the metal-containing film MF formed on the side surface SS of the mask MK may become thinner from the upper surface TP of the mask MK toward the bottom portion of the opening OP. That is, the metal-containing film MF may be a sub-conformal film. In the bottom portion of the opening OP of the mask MK, the metal-containing film MF does not need to be formed on the etching target film EF. That is, the metal-containing film may not be formed on the etching target film EF. Also, the thickness of the metal-containing film MF formed in the bottom portion of the opening OP of the mask MK may be thinner than the thickness of the metal-containing film MF formed on the upper surface TP and the side surface SS of the mask MK.

The metal-containing film MF may be a conformal film. In this case, for example, after the metal-containing film MF formed in the bottom portion of the opening OP is selectively removed by anisotropic etching, Step ST2 to be described later may be performed. Accordingly, whereas the metal-containing film MF may be left on the upper surface TP and the side surface SS of the mask MK, the metal-containing film MF in the bottom portion of the opening OP of the mask MK can be removed.

The metal-containing film MF may include at least one type of metal selected from the group including tungsten (W), molybdenum (Mo), ruthenium (Ru), tin (Sn), titanium (Ti), tantalum (Ta), hafnium (Hf), chromium (Cr), and germanium (Ge), may include at least one type of metal selected from the group including W, Mo, Ru, and Sn, and may include a W-containing film. The metal-containing film MF may include carbide and/or silicide of the metal described above. In an example, the metal-containing film MF may include tungsten carbide (WC) and/or tungsten silicide (WSi).

The metal-containing film MF may be formed by chemical vapor deposition (CVD). The chemical vapor deposition may include plasma CVD. The metal-containing film MF may be formed by using a processing gas containing a metal-containing gas. The processing gas is an example of a second processing gas. In one embodiment, the metal-containing film MF may be formed by plasma generated from the processing gas.

In a case where the metal-containing film MF is formed by using plasma CVD, first, the processing gas containing the metal-containing gas is supplied from the gas supply 20 into the plasma processing space 10s. Next, the source RF signal is supplied to the lower electrode of the substrate support 11 and/or the upper electrode of the shower head 13. In this way, a radio-frequency electric field is generated between the shower head 13 and the substrate support 11, so that plasma is generated from the processing gas in the plasma processing space 10s. In this case, a bias signal does not need to be supplied to the lower electrode of the substrate support 11. Further, the bias signal may be supplied to the lower electrode of the substrate support 11. In this case, a level (e.g., power level or voltage level) of the bias signal may be lower than a level of the bias signal supplied to the substrate support 11 in Step ST3. The bias signal may be a bias RF signal, or may be a bias DC signal.

In one embodiment, during processing in Step ST2, the temperature of the substrate support 11 or the substrate W may be controlled to the same temperature as the temperature set in Step ST1, or may be controlled to a different temperature (for example, a temperature higher than the temperature set in Step ST1).

In Step ST2, the metal-containing gas included in the processing gas may be a gas containing at least one of metal (hereinafter, also referred to as “metal M”) selected from the group including tungsten (W), molybdenum (Mo), ruthenium (Ru), tin (Sn), titanium (Ti), tantalum (Ta), hafnium (Hf), chromium (Cr), and germanium (Ge). The gas containing the metal M may be a gas containing oxide, nitride, sulfide, or halide of the metal M. For example, the processing gas may be a gas containing the halide of the metal M, or may be a gas containing fluoride of the metal M. In an example, the processing gas may include WF₆-containing gas, WCl₆ gas, or the like. In an example, the metal-containing gas may be WF₂ gas, WF₄ gas, WF₅ gas, WF₆ gas, WCl₂ gas, WCl₄ gas, WCl₅ gas, WCl₆ gas, MoF₄ gas, MoCl₆ gas, TiCl₄ gas, or the like. In an example, the metal-containing gas may be RuO₃ gas, RuO₄ gas, RuF₅ gas, or RuF₆ gas. In one embodiment, the processing gas further includes an inert gas. The inert gas may be, for example, a noble gas such as Ar gas, He gas, or Kr gas, or a nitrogen gas.

In Step ST2, the processing gas may further include an oxidizing gas or a reducing gas. As the oxidizing gas, oxygen (O₂), carbon monoxide (CO), carbon dioxide (CO₂), or the like may be used. As the reducing gas, a hydrogen-containing gas such as hydrogen (H₂) may be used.

In Step ST2, the processing gas may further include an additive gas such as a carbon-containing gas or a silicon-containing gas. When the processing gas includes the carbon-containing gas, a metal carbide film may be formed as the metal-containing film MF. For example, when the processing gas includes a tungsten-containing gas and a carbon-containing gas, a tungsten carbide film may be formed as the metal-containing film MF. The carbon-containing gas may be a hydrocarbon gas such as methane (CH₄). Further, when the processing gas includes the silicon-containing gas, a metal silicide may be formed as the metal-containing film MF. For example, when the processing gas includes the tungsten-containing gas and the silicon-containing gas, a tungsten silicide film may be formed as the metal-containing film MF. The silicon-containing gas may be an aminosilane gas or the like.

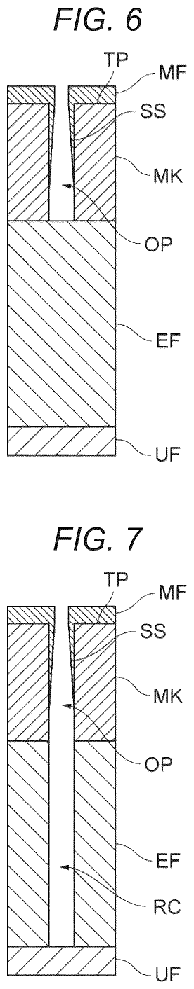

FIG. 6 is a view illustrating an example of the cross-sectional structure of the substrate W after processing in Step ST2. As illustrated in FIG. 6, the metal-containing film MF is formed on a surface of the mask MK through the processing in Step ST2 and may not be formed on the etching target film EF). The metal-containing film MF is a film including the metal M included in the processing gas used in Step ST2. In one embodiment, the metal-containing film MF is continuously formed from the upper surface TP of the mask MK to the sidewall SS of the mask MK. In one embodiment, the metal-containing film MF may be formed over at least a portion of the bottom portion (i.e., surface of the etching target film EF) of the opening OP from the sidewall SS of the mask MK. The metal-containing film MF may provide protection for the mask MK in etching the etching target film EF in Step ST3.

In Step ST2, the metal-containing film MF may be formed by atomic layer deposition (ALD) or molecular layer deposition (MLD).

When the metal-containing film MF is formed by the ALD or the MLD, a gas containing a precursor and a reaction gas are used as the processing gas. In this case, the substrate W may be exposed to plasma generated from the reaction gas after being exposed to the gas containing the precursor. When the substrate W is exposed to the gas containing the precursor, the precursor gas is adsorbed by the surface of the mask MK to form a precursor layer. In this state, when the substrate W is exposed to the plasma generated from the reaction gas, the metal-containing film MF is formed from the precursor layer. After the substrate W is exposed to the gas containing the precursor and/or after the substrate W is exposed to the plasma generated from the reaction gas, a noble gas or a nitrogen gas may be supplied into the chamber to purge the gas or the reaction gas containing the excess precursor. Further, when the sub-conformal metal-containing film MF is formed on the surface of the mask MK by the ALD or the MLD, the supply of the gas containing the precursor may be stopped before the precursor is completely adsorbed to the surface of the mask MK, or the reaction between the precursor layer and the reaction gas may be stopped before the metal-containing film MF is completely formed from the precursor layer.

The gas containing the precursor may be the metal-containing gas. As an example, the metal-containing gas may be a gas containing the metal M described above. The reaction gas may be an oxidizing gas that oxidizes the precursor or a reducing gas that reduces the precursor. As an example, the oxidizing gas may be oxygen (O₂), carbon monoxide (CO), carbon dioxide (CO₂), or the like. As an example, the reducing gas may be a hydrogen-containing gas such as hydrogen (H₂).

When the metal-containing film is formed by the ALD or the MLD in Step ST2, the processing gas may include an additive gas such as the carbon-containing gas and/or the silicon-containing gas, in addition to the metal-containing gas described above as the precursor gas. In this case, the substrate W may be alternately exposed to the metal-containing gas and the additive gas. Further, the substrate W may be exposed to a mixed gas containing the metal-containing gas and the additive gas. When the processing gas includes the carbon-containing gas as the additive gas, the metal carbide film may be formed as the metal-containing film MF. For example, when the processing gas includes the tungsten-containing gas and the carbon-containing gas as the precursor gas, the tungsten carbide film may be formed as the metal-containing film MF. The carbon-containing gas may include the hydrocarbon gas such as methane (CH₄). Further, when the processing gas includes the silicon-containing gas as the additive gas, the metal silicide film may be formed as the metal-containing film MF. For example, when the processing gas includes the tungsten-containing gas and the silicon-containing gas as the precursor gas, the tungsten silicide film may be formed as the metal-containing film MF. The silicon-containing gas may include the aminosilane gas or the like.

In Step ST2, the temperature of the substrate support 11 on which the substrate W is supported may be adjusted to 0° C. or higher, 50° C. or higher, or 100° C. or higher. The temperature of the substrate support 11 may be adjusted by the temperature of the heat transfer fluid flowing through a flow path provided in the substrate support 11, the temperature of the heater provided in the substrate support 11, or a lamp provided in the chamber. Since the metal-containing film MF is formed in a state where the temperature of the substrate support 11 is high, an advantageous effect of improving a selectivity of the mask MK (e.g., ratio of the etching rate of the etching target film EF to the etching rate of the mask MK) may be improved in Step ST3.

In one embodiment, after the metal-containing film MF is formed, the substrate W may be subjected to a thermal treatment. Since the substrate W is subjected to the thermal treatment, the selectivity of the mask MK in Step ST3 may be improved even when the metal-containing film MF is formed at a low temperature. The thermal treatment may be performed by heating the substrate W by using the temperature of the heat transfer fluid flowing through the flow path provided in the substrate support 11, the temperature of the heater provided in the substrate support 11, or the lamp provided in the chamber. In the thermal treatment, the temperature of the substrate W or the substrate support 11 may be set to 100° C. or higher or 150° C. or higher.

In Step ST2, the metal-containing film MF may be formed on the mask MK by physical vapor deposition (PVD). As an example, the physical vapor deposition may be performed as follows. First, the source RF signal is supplied to the lower electrode of the substrate support 11 and/or at least one upper electrode of the shower head 13. Accordingly, a radio-frequency electric field is generated between the shower head 13 and the substrate support 11, and the plasma is generated from the processing gas in the chamber 10. In this case, the bias signal may be supplied to the upper electrode of the shower head 13. The upper electrode is an example of a metal-containing electrode. A timing at which the bias signal starts to be supplied may be the same as or different from a timing at which the source RF signal starts to be supplied. The bias signal may be the second DC signal generated by the second DC generator 32b. The second DC signal may have a negative polarity. When the plasma is generated in the chamber 10, ions in the plasma are attracted and collided with the surface of the shower head 13 having a negative potential. A metal-containing material 132 forming the surface of the shower head 13 is sputtered (e.g., physical sputtering), and metal or secondary electrons are emitted into the plasma. The emitted metal falls onto the substrate W. Accordingly, as illustrated in FIG. 6, the metal-containing film MF including the metal is formed on the surface of the mask MK. The metal-containing film MF may function as a protective film for the mask MK in etching processing. The secondary electrons emitted into the plasma may contribute to improvement of plasma density and neutralization of a charged state of the substrate W. Accordingly, the etching rate of the film EF and perpendicularity of the ions entering the substrate W may be improved. In one embodiment, the bias signal supplied to the upper electrode may be the bias RF signal. For example, in the plasma processing apparatus 1, the second RF generator 31b may be configured to be electrically connected to the upper electrode, and the upper electrode may be sputtered by supplying the bias RF signal generated in the second RF generator 31b to the upper electrode.

### (Step ST3: Etching of an Etching Target Film)

In Step ST3, the etching target film EF is etched by using the processing gas. The processing gas is an example of a first processing gas. In one embodiment, the etching target film EF may be etched by being exposed to the plasma generated from the processing gas via the mask MK on which the metal-containing film MF is formed.

In Step ST3, the processing gas is supplied from the gas supply 20 into the plasma processing space 10s. The source RF signal is supplied to the lower electrode of the substrate support 11 and/or the upper electrode of the shower head 13. In this way, a radio-frequency electric field is generated between the shower head 13 and the substrate support 11, so that plasma is generated from the processing gas in the plasma processing space 10s. In one embodiment, the bias signal may be supplied to the lower electrode of the substrate support 11. Accordingly, an active species such as ions and radicals in the plasma are attracted to the substrate W, and the recess RC of the etching target film EF is further etched in a depth direction (i.e., the depth direction being the direction in which the etching target film EF is formed/stacked on the underlying film UF). The bias signal may be the bias RF signal supplied from the second RF generator 31b. The bias signal may be the bias DC signal supplied from the first DC generator 32a.

The bias signal may be RF power for bias. Further, instead of the RF power for bias, a pulse voltage other than the RF power may be applied. The pulse voltage is a pulse-shaped voltage supplied from a pulse power source. The pulse power source may be configured such that the power source itself supplies a pulse wave, and may include a device for pulsing a voltage on a downstream side of the pulse power source. In an example, the pulse voltage is supplied to the substrate support such that a negative potential is generated in the substrate. The pulse voltage may be a pulse of a negative polarity direct-current voltage. Further, the pulse voltage may be a pulse of a rectangular wave, may be a pulse of a triangular wave, may be an impulse, or may have a pulse of another voltage waveform.

In one embodiment, the temperature of the substrate support 11 or the substrate W may be controlled to a given temperature set in Step ST11 during the processing in Step ST3. The temperature of the substrate support 11 or the substrate W in Step ST3 may be controlled to be lower than the temperature of the substrate support 11 or the substrate W in Step ST2. The temperature of the substrate support 11 or the substrate W may be set to, for example, 0° C. or lower, −10° C. or lower, −20° C. or lower, −30° C. or lower, −40° C. or lower, −50° C. or lower, −60° C. or lower, or −70° C. or lower. The temperature of the substrate support 11 or the substrate W may be controlled by the temperature of the heat transfer fluid flowing through the flow path provided in the substrate support 11, the temperature of the heater provided in the substrate support 11, or the lamp provided in the chamber.

Through the etching in Step ST3, a recess is formed in the etching target film EF, based on a shape of the opening OP of the mask MK. When a given stop condition is satisfied, the etching in Step ST3 is stopped, and the present processing method is completed. For example, the stop condition may be set, based on an etching time, the depth of the recess, or the like. For example, the aspect ratio of the recess RC when the etching is completed may be 20 or higher, and may be 30 or higher, 40 or higher, 50 or higher, or 100 or higher.

In Step ST3, the processing gas may be selected, based on a type of the etching target film EF. For example, when the etching target film EF is the silicon-containing film, the processing gas may include a fluorine-containing gas. For example, the fluorine-containing gas may be a hydrogen fluoride gas (HF gas), a fluorocarbon gas, or a hydrofluorocarbon gas.

In Step ST3, when the processing gas includes the HF gas, a flow rate (i.e., molar flow rate or partial pressure) of the HF gas in the processing gas may be maximized. In an example, the flow rate of the HF gas may be maximized in the processing gas, except for the inert gas. In an example, the flow rate of the HF gas may be 50% by volume or more, 60% by volume or more, 70% by volume or more, 80% by volume or more, 90% by volume or more, or 95% by volume or more with respect to a total flow rate of the processing gas (when the processing gas includes the inert gas, the flow rates of all gases except for the inert gas). The flow rate of the HF gas may be less than 100% by volume, 99.5% by volume or less, 98% by volume or less, or 96% by volume or less with respect to the total flow rate of the processing gas. In an example, the flow rate of the HF gas is 70% by volume or more and 96% by volume or less with respect to the total flow rate of the processing gas.

In Step ST3, the processing gas may further include a phosphorus-containing gas. The phosphorus containing gas is a gas containing a phosphorus containing molecule.

In one embodiment, the phosphorus containing molecule may be an oxide such as tetraphosphorus pentoxide (P₄O₁₀), tetraphosphorus octoxide (P₄O₈), or tetraphosphorus hexaoxide (P₄O₆). The tetraphosphorus decaoxide is sometimes called diphosphorus pentoxide (P₂O₅). The phosphorus containing molecule may be a halide (phosphorus halide), such as phosphorus trifluoride (PF₃), phosphorus pentafluoride (PF₅), phosphorus trichloride (PCl₃), phosphorus pentachloride (PCl₅), phosphorus tribromide (PBr₃), phosphorus pentabromide (PBr₅), and phosphorus iodide (PI₃). That is, the phosphorus containing molecule may contain fluorine as a halogen element, such as phosphorus fluoride. Alternatively, the phosphorus containing molecule may contain a halogen element other than fluorine, as the halogen element. The phosphorus containing molecule may be halogenated phosphoryl, such as phosphoryl fluoride (POF₃), phosphoryl chloride (POCl₃), and phosphoryl bromide (POBr₃). The phosphorus containing molecule may be phosphine (PH₃), calcium phosphide (such as Ca₃P₂), phosphoric acid (H₃PO₄), sodium phosphate (Na₃PO₄), hexafluorophosphoric acid (HPF₆), or the like. The phosphorus containing molecule may be fluorophosphines (HgPFh). Here, the sum of g and h is 3 or 5. As the fluorophosphine, HPF₂ and H₂PF₃ are exemplified. The processing gas may include one or more phosphorus containing molecules in the phosphorus containing molecules described above, as at least one phosphorus containing molecule. For example, the processing gas may include at least one of PF₃, PCl₃, PF₅, PCl₅, POCl₃, PH₃, PBr₃, or PBr₅, as at least one phosphorus containing molecule. In a case where each phosphorus containing molecule contained in the processing gas is a liquid or a solid, each phosphorus containing molecule may be evaporated by heating or the like, and may be supplied into the plasma processing space.

In one embodiment, the phosphorus-containing gas may be PClₐF_{b} (a is an integer of 1 or more, b is an integer of 0 or more, and a+b is an integer of 5 or less) gas, or PC_{c}H_{d}Fₑ (d and e are each integers of 1 or more and 5 or less, and c is an integer of 0 or more and 9 or less) gas.

The PClₐF_{b} gas may be, for example, at least one type of gas selected from the group including PClF₂ gas, PCl₂F gas, and PCl₂F₃ gas.

The PC_{c}H_{d}Fₑ gas may be, for example, at least one type of gas selected from the group including PF₂CH₃ gas, PF(CH₃)₂ gas, PH₂CF₃ gas, PH(CF₃)₂ gas, PCH₃(CF₃)₂ gas, PH₂F gas, and PF₃(CH₃)₂ gas.

In one embodiment, the phosphorus-containing gas may be a PCl_{c}F_{d}CₑH_{f} (c, d, e, and f are each integers of 1 or more) gas. Further, the phosphorus containing gas may be a gas containing phosphorus (P), fluorine (F), and halogen (for example, Cl, Br, or I) other than F (fluorine) in its molecular structure, a gas containing phosphorus (P), fluorine (F), carbon (C), and hydrogen (H) in its molecular structure, or a gas containing phosphorus (P), fluorine (F), and hydrogen (H) in its molecular structure.

In one embodiment, the phosphorus-containing gas may be phosphine-based gas. The phosphine-based gas may be phosphine (PH₃), a compound in which at least one hydrogen atom of the phosphine is replaced with an appropriate substituent, or a phosphinic acid derivative.

The substituent for replacing the hydrogen atom of the phosphine is not particularly limited, and may be, for example, a halogen atom such as a fluorine atom or a chlorine atom; an alkyl group such as a methyl group, an ethyl group, or a propyl group; and a hydroxyalkyl group such as a hydroxymethyl group, a hydroxyethyl group, or a hydroxypropyl group. In an example, the substituent may be a chlorine atom, a methyl group, and a hydroxymethyl group.

The phosphinic acid derivative may be phosphinic acid (H₃O₂P), alkylphosphinic acid (PHO(OH)R), and dialkylphosphinic acid (PO(OH)R₂).

As the phosphine-based gas, for example, at least one type of gas selected from the group including PCH₃Cl₂ (dichloro(methyl)phosphine) gas, P(CH₃)₂Cl (chloro(dimethyl)phosphine) gas, P(HOCH₂)Cl₂ (dichloro(hydroxymethyl)phosphine) gas, P(HOCH₂)₂Cl (chloro(dihydroxymethyl)phosphine) gas, P(HOCH₂)(CH₃)₂ (dimethyl(hydroxymethyl)phosphine) gas, P(HOCH₂)₂(CH₃) (methyl(dihydroxymethyl)phosphine) gas, P(HOCH₂)₃ (tris(hydroxymethyl)phosphine) gas, H₃O₂P (phosphinic acid) gas, PHO(OH)(CH₃)(methyl phosphinic acid) gas, and PO(OH)(CH₃)₂(dimethylphosphinic acid) gas may be used.

In Step ST3, the flow rate of the phosphorus-containing gas contained in the processing gas may be 20% by volume or less, 10% by volume or less, or 5% by volume or less of the total flow rate of the processing gas.

In Step ST3, the processing gas may further include a tungsten-containing gas. The tungsten-containing gas may be a gas containing tungsten and halogen, and in an example, is WFₓCl_{y} gas (x and y are each integers of 0 or more and 6 or less, and a sum of x and y is 2 or more and 6 or less). Specifically, the tungsten-containing gas may be a gas containing tungsten and fluorine, such as tungsten difluoride (WF₂) gas, tungsten tetrafluoride (WF₄) gas, tungsten pentafluoride (WF₅) gas, and tungsten hexafluoride (WF₆) gas, or a gas containing tungsten and chlorine, such as tungsten dichloride (WCl₂) gas, tungsten tetrachloride (WCl₄) gas, tungsten pentachloride (WCl₅) gas, and tungsten hexachloride (WCl₆) gas. Among these, at least any gas of a WF₆ gas and a WCl₆ gas may be used. The flow rate of the tungsten-containing gas may be 5% by volume or less of the total flow rate of the processing gas. The processing gas may include at least one of a titanium-containing gas, a ruthenium-containing gas, and/or a molybdenum-containing gas, instead of or in addition to the tungsten-containing gas.

In Step ST3, the processing gas may further include a carbon-containing gas. The carbon-containing gas may be a fluorocarbon gas and/or a hydrofluorocarbon gas. For example, the fluorocarbon gas may include at least one type selected from the group including CF₄ gas, C₂F₂ gas, C₂F₄ gas, C₃F₆ gas, C₃F₈ gas, C₄F₆ gas, C₄F₈ gas, and C₅F₈ gas. For example, the hydrofluorocarbon gas may include at least one type selected from the group including CHF₃ gas, CH₂F₂ gas, CH₃F gas, C₂HF₅ gas, C₂H₂F₄ gas, C₂H₃F₃ gas, C₂H₄F₂ gas, C₃HF₇ gas, C₃H₂F₂ gas, C₃H₂F₄ gas, C₃H₂F₆ gas, C₃H₃F₅ gas, C₄H₂F₆ gas, C₄H₅F₅ gas, C₄H₂F₈ gas, C₅H₂F₆ gas, C₅H₂F₁₀ gas, and C₅H₃F₇ gas. In one embodiment, the carbon-containing gas is a linear gas having unsaturated bond. As this gas, for example, C₃F₆ (hexafluoropropene) gas, C₄F₈ (octafluoro-1-butene, octafluoro-2-butene) gas, C₃H₂F₄ (1,3,3,3-tetrafluoropropene) gas, C₄H₂F₆ (trans-1,1,1,4,4,4-hexafluoro-2-butene) gas, C₄F₈O (pentafluoroethyl trifluorovinyl ether) gas, CF₃COF gas (1,2,2,2-tetrafluoroethane-1-one), CHF₂COF (difluoroacetic acid fluoride) gas, and COF₂ (carbonyl fluoride) gas may be used. In one embodiment, the carbon-containing gas may include a halogen element other than fluorine, and may include a halogen element other than fluorine and fluorine. This gas may be CᵢHⱼFₖXₗ. Here, X is halogen other than fluorine. Further, i and l may be integers of 1 or more, and j and k may be integers of 0 or more. The carbon-containing gas may include, for example, one or more gases among gases of CHₗClₗ, CFₖBrₗ, CFₖIₗ, and CᵢFₖClₗ. More specifically, the carbon-containing gas may be at least one type of gas selected from the group including CHCl₃, CH₂Cl₂, and CF₂Br₂.

In Step ST3, the processing gas may further include an oxygen-containing gas. The oxygen-containing gas may be, for example, at least one type of gas selected from the group including O₂, CO, CO₂, H₂O, and H₂O₂. In an example, the oxygen-containing gas may be an oxygen-containing gas other than H₂O, for example, at least one type of gas selected from the group including O₂, CO, CO₂, and H₂O₂. The flow rate of the oxygen-containing gas may be adjusted depending on the flow rate of another gas (for example, the carbon-containing gas) included in the processing gas.

In Step ST3, the processing gas may further include a halogen-containing gas other than fluorine. Here, the gas containing halogen other than fluorine may be a chlorine-containing gas, a bromine-containing gas, and/or an iodine-containing gas. In an example, the chlorine-containing gas may be at least one type of gas selected from the group including HCl, Cl₂, SiCl₂, SiCl₄, CCl₄, SiH₂Cl₂, Si₂Cl₆, CHCl₃, SO₂Cl₂, BCl₃, PCl₃, PCl₅, and POCl₃. In an example, the bromine-containing gas may be at least one type of gas selected from the group including Br₂, HBr, CBr₂F₂, C₂F₅Br, PBr₃, PBr₅, POBr₃, and BBr₃. In an example, the iodine-containing gas may be at least one type of gas selected from the group including HI, CF₃I, C₂F₅I, C₃F₇I, IF₅, IF₇, I₂, and PI₃. In an example, the gas containing halogen other than fluorine may be at least one type selected from the group including HCl gas, Cl₂ gas, Br₂ gas, and HBr gas. In an example, the gas containing halogen other than fluorine is HCl gas, Cl₂ gas or HBr gas.

In Step ST3, the processing gas may further include an inert gas. The inert gas is a noble gas such as Ar gas, He gas, or Kr gas and/or a nitrogen gas.

In Step ST3, the processing gas may include a gas capable of generating a hydrogen fluoride species (HF species) in plasma, instead of a portion or all of the HF gas. The HF species includes at least any one of a gas, a radical, and an ion of hydrogen fluoride.

The gas capable of generating the HF species may be a single gas or a mixed gas containing hydrogen (H) and fluorine (F). The single gas containing H and F may be, for example, a hydrofluorocarbon gas. The hydrofluorocarbon gas may have 2 or more, 3 or more, or 4 or more carbon atoms. In an example, the hydrofluorocarbon gas is at least one type selected from the group including CH₂F₂ gas, C₃H₂F₄ gas, C₃H₂F₆ gas, C₃H₃F₅ gas, C₄H₂F₆ gas, C₄H₅F₅ gas, C₄H₂F₈ gas, C₅H₂F₆ gas, C₅H₂F₁₀ gas, and C₅H₃F₇ gas. In an example, the hydrofluorocarbon gas is at least one type selected from the group including CH₂F₂ gas, C₃H₂F₄ gas, C₃H₂F₆ gas, and C₄H₂F₆ gas.

The mixed gas containing H and F may be, for example, a mixed gas containing a hydrogen source and a fluorine source. The hydrogen source may be, for example, at least one type selected from the group including H₂ gas, NH₃ gas, H₂O gas, H₂O₂ gas, and a hydrocarbon gas (such as CH₄ gas or C₃H₆ gas). The fluorine source may be, for example, a carbon-free fluorine-containing gas such as NF₃ gas, SF₆ gas, WF₆ gas, or XeF₂ gas. Further, the fluorine source may be a fluorine-containing gas containing carbon, such as a fluorocarbon gas and a hydrofluorocarbon gas. In an example, the fluorocarbon gas may be at least one type selected from the group including CF₄ gas, C₂F₂ gas, C₂F₄ gas, C₃F₆ gas, C₃F₈ gas, C₄F₆ gas, C₄F₈ gas, and C₅F₈ gas. In an example, the hydrofluorocarbon gas may be at least one type selected from the group including CHF₃ gas, CH₂F₂ gas, CH₃F gas, C₂HF₅ gas, and a hydrofluorocarbon gas containing three or more C's (C₃H₂F₄ gas, C₃H₂F₆ gas, C₄H₂F₆ gas, and the like).

The processing gas used in Step ST3 is not limited to the above-described gases. For example, it is also possible to apply a processing gas disclosed in U.S. Pat. No. 11,342,194 or International Publication No. WO2021/090798.

In one embodiment, the type of gas included in the processing gas and the flow rate (partial pressure) thereof may be constant during the processing in Step ST3, or may be changed as the etching is progressively performed.

FIG. 7 is a view illustrating an example of the cross-sectional structure of the substrate W after processing in Step ST3. As illustrated in FIG. 7, the etching target film EF is etched in the depth direction by the processing in Step ST3. As described above, in Step ST2, the metal-containing film MF containing the metal M (ruthenium, tungsten, molybdenum, and/or titanium) is formed on the mask MK. The metal-containing film MF containing the metal M has low reactivity with an active species of hydrogen fluoride in the plasma generated in Step ST3. The metal-containing film MF has higher etching resistance with respect to the plasma generated in Step ST3 than the etching target film EF. The metal-containing film MF functions as a protective film for the mask MK in the etching in Step ST3. Accordingly, the selectivity of the etching of the etching target film EF with respect to the etching of the mask MK may be improved. Further, it is possible to suppress occurrence of bowing in the etching target film EF.

After Step ST3 is completed, the metal-containing film MF may be removed. In an example, after Step ST3 is completed, the metal-containing film MF is removed when the mask MK is removed. The mask MK may be removed by dry processing or may be removed by wet processing.

According to one embodiment of the present disclosure, the etching target film EF is etched in a state where the metal-containing film MF is formed on the surface of the mask MK of the substrate W. The metal-containing film MF has higher etching resistance to the plasma than the mask MK. Therefore, it is possible to suppress consumption of the mask MK when the etching target film EF is etched. That is, it is possible to improve the selectivity in the etching (ratio of the etching rate of the etching target film EF to the etching rate of the mask MK). Further, since the consumption of the mask MK is suppressed, it is possible to suppress the occurrence of bowing in the etching target film EF.

### Modification Examples

The present method may be modified in various ways without departing from the scope and the concept of the present disclosure.

In one embodiment, Step ST1 may include a step of forming the opening OP in the mask MK. That is, Step ST1 may include a step of disposing the substrate W in which the opening OP is not formed on the mask MK in the substrate support 11, and a step of forming the opening OP in the mask MK.

In one embodiment, Step ST1 may include a step of disposing the substrate W in which the metal-containing film MF is formed on the mask MK in the substrate support 11. That is, in one embodiment, Step ST3 may be performed after Step ST1 is performed. In this case, Step ST2 may be performed outside the plasma processing apparatus 1 before Step ST1.

The plasma processing apparatus for performing Steps ST1 to ST3 is not particularly limited, and various plasma processing apparatuses can be used. As an example, in addition to the capacitively-coupled plasma processing apparatus illustrated in FIG. 2, an inductively-coupled plasma processing apparatus may be used, an electron cyclotron resonance (ECR) plasma processing apparatus may be used, or a combination of two or more types thereof may be used. For example, a step (Step ST2) of forming the metal-containing film MF on the surface of the mask MK may be performed by the inductively-coupled or capacitively-coupled plasma processing apparatus, and a step (Step ST3) of etching the etching target film EF may be performed by the capacitively-coupled plasma processing apparatus. Further, when the opening OP is formed in the mask MK in Step ST1, the opening OP may be formed in the mask MK by the inductively-coupled plasma processing apparatus.

In one embodiment, Step ST2 and Step ST3 may be repeated. That is, Step ST2 and Step ST3 may be performed as one cycle, and the cycle may be repeated multiple times. In this case, forming the metal-containing film MF on the sidewall SS of the mask MK and etching the etching target film EF are alternately repeated.

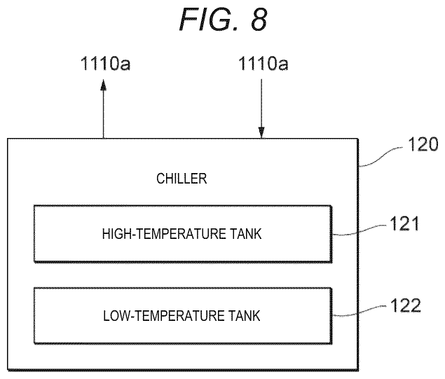

In one embodiment, the temperature of the substrate support 11 or the substrate W in Step ST2 and Step ST3 may be controlled by a chiller. FIG. 8 is a view illustrating an example of the chiller. The chiller illustrated in FIG. 8 includes a high-temperature tank 121 that stores a heat transfer fluid whose temperature is controlled to a first temperature, and a low-temperature tank 122 that stores a heat transfer fluid whose temperature is controlled to a second temperature lower than the first temperature. The heat transfer fluid whose temperature is controlled to the first temperature may be used for controlling the temperature of the substrate support 11 or the substrate W in Step ST2. The heat transfer fluid whose temperature is controlled to the second temperature may be used for controlling the temperature of the substrate support 11 or the substrate W in Step ST3. That is, in Step ST2, a chiller 120 may feed the heat transfer fluid whose temperature is controlled to the first temperature from the high-temperature tank 121 to the flow path 1110a. Accordingly, the temperature of the substrate support 11 or the substrate W may be controlled to a predetermined temperature. Further, in Step ST3, the chiller 120 may feed the heat transfer fluid whose temperature is controlled to the second temperature from the low-temperature tank 122 to the flow path 1110a. Accordingly, the temperature of the substrate support 11 or the substrate W may be controlled to a predetermined temperature. As an example, the high-temperature tank 121 may store the heat transfer fluid of 180° C., however the present application is not limited thereto. As an example, the low-temperature tank 122 may store the heat transfer fluid of −70° C., however the present application is not limited thereto.

### Experiment 1

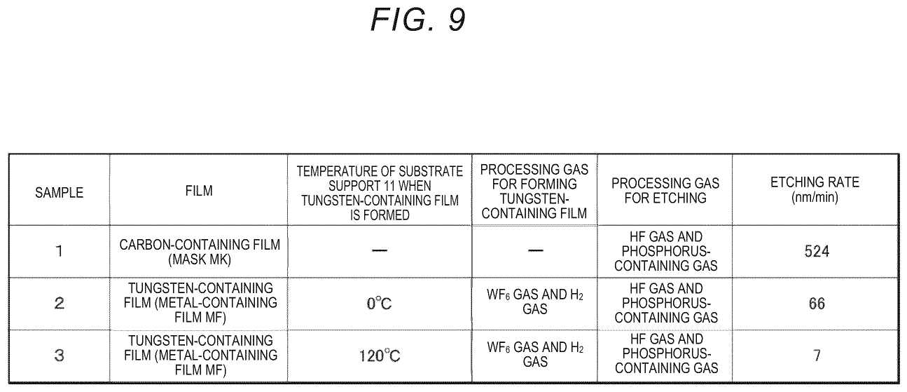

FIG. 9 is a table illustrating experimental conditions and experimental results of Experiment 1. In Experiment 1, an advantageous effect of improving the selectivity by the metal-containing film MF is confirmed. In Experiment 1, Sample 1 is a sample for confirming the etching rate of the carbon-containing film (mask MK). Further, Samples 2 and 3 are samples for confirming the etching rate of the tungsten-containing film (metal-containing film MF).

In Sample 2, the tungsten-containing film is formed by setting the temperature of the substrate support 11 to 0° C. and generating the plasma from the processing gas containing WF₆ gas and H₂ gas. Meanwhile, in Sample 3, the tungsten-containing film is formed by setting the temperature of the substrate support 11 to 120° C. and generating the plasma from the processing gas containing the WF₆ gas and the H₂ gas. In Samples 2 and 3, the tungsten-containing film is formed under the same conditions except for the temperature of the substrate support 11.

Further, the carbon-containing film of Sample 1 and the tungsten-containing films of Samples 2 and 3 are etched by the plasma generated from the processing gas containing the HF gas and the phosphorus-containing gas.

As illustrated in FIG. 9, the etching rate of the tungsten-containing film of Sample 2 is significantly lower than the etching rate of the carbon-containing film of Sample 1. Accordingly, the followings are understood. Since the metal-containing film MF such as the tungsten-containing film is formed on the surface of the mask MK, it is possible to improve the selectivity of the mask MK (mask MK protected by the metal-containing film MF) with respect to the etching target film EF in the etching of the etching target film EF.

Further, the etching rate of the tungsten-containing film of Sample 3 is much lower than the etching rate of the tungsten-containing film of Sample 2. Accordingly, the followings are confirmed. Since the temperature of the substrate support 11 or the substrate W is controlled when the metal-containing film MF is formed, it is possible to improve the selectivity of the mask MK (mask MK protected by the metal-containing film MF) with respect to the etching target film EF.

### Experiment 2

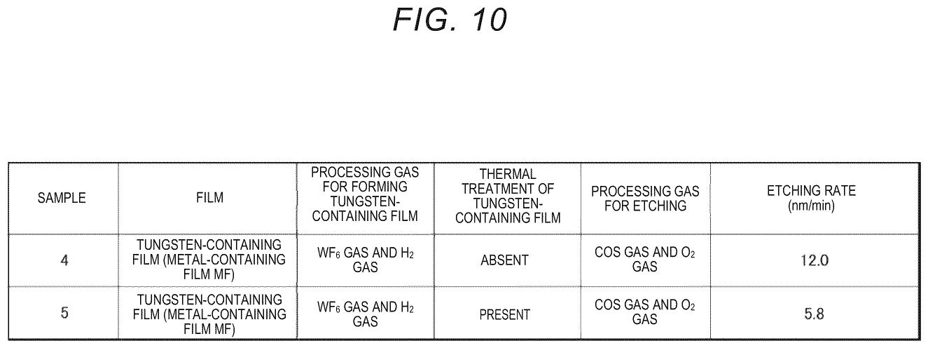

FIG. 10 is a table illustrating experimental conditions and experimental results of Experiment 2. In Experiment 2, an advantageous effect of improving the selectivity by the thermal treatment of the metal-containing film MF is confirmed. In Experiment 2, Samples 4 and 5 are samples for confirming the etching rate of the tungsten-containing film (metal-containing film MF).

In Samples 4 and 5, the tungsten-containing film is formed by generating the plasma from the processing gas containing the WF₆ gas and the H₂ gas. In addition, in Samples 4 and 5, the tungsten-containing film is formed by controlling the temperature of the substrate support 11 to 20° C. Further, in Sample 4, after the tungsten-containing film is formed, no thermal treatment is performed on the tungsten-containing film. Meanwhile, in Sample 5, after the tungsten-containing film is formed, the thermal treatment at 180° C. is performed on the tungsten-containing film. In Samples 4 and 5, the tungsten-containing film is formed under the same conditions except for the thermal treatment.

Further, the tungsten-containing films of Samples 4 and 5 are etched by the plasmas generated from the processing gas containing the COS gas and the O₂ gas.

As illustrated in FIG. 10, the etching rate of the tungsten-containing film of Sample 5 subjected to the thermal treatment is significantly lowered than the etching rate of the tungsten-containing film of Sample 4 which is not subjected to the thermal treatment. Accordingly, the following is confirmed. Since the thermal treatment is performed on the tungsten-containing film, it is possible to improve the selectivity of the mask MK (mask MK protected by the metal-containing film MF) with respect to the etching target film EF.

### Experiment 3

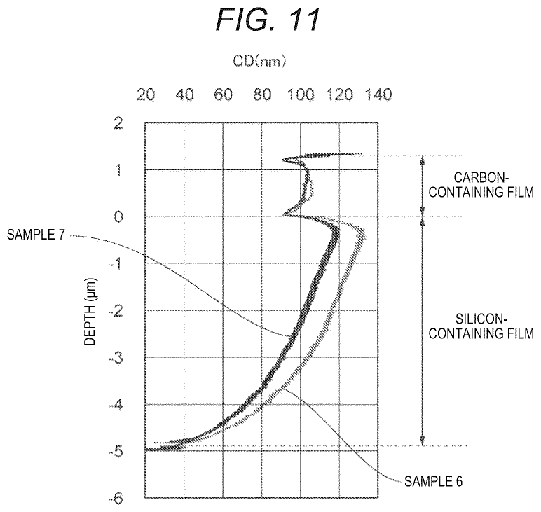

FIG. 11 is a view illustrating experimental results of Experiment 3. In Experiment 3, an advantageous effect of improving the bowing by the metal-containing film MF is confirmed. In Experiment 3, Samples 6 and 7 are samples including the carbon-containing film (mask MK) in which the opening OP is formed on the silicon-containing film (etching target film EF). In Sample 6, no tungsten-containing film (metal-containing film MF) is formed on the carbon-containing film. Meanwhile, in Sample 7, the tungsten-containing film (metal-containing film MF) is formed on the carbon-containing film (mask MK). Samples 6 and 7 have the same structure except for the presence or absence of the tungsten-containing film.

In addition, in Samples 6 and 7, the silicon-containing film is etched by the plasma generated from the processing gas containing the HF gas and the phosphorus-containing gas. Samples 6 and 7 are etched under the same conditions.

As illustrated in FIG. 11, the followings are confirmed. Compared to Sample 6, in Sample 7, a critical dimension (CD) of the recess RC is improved in the upper portion of the recess RC formed in the silicon-containing film (etching target film EF). That is, in Sample 7, it is confirmed that the bowing of the recess RC is improved by forming the tungsten-containing film on the carbon-containing film. Further, as illustrated in FIG. 11, it is also confirmed that in Sample 7, the CD of the opening OP formed in the carbon-containing film is improved.

Embodiments of the present disclosure may further include the following aspects.

### APPENDIX 1

An etching method includes (a) providing a substrate including a silicon-containing film and a mask on the silicon-containing film, the mask including an opening pattern, (b) forming a metal-containing film on the mask, and (c) etching the silicon-containing film by generating plasma from a first processing gas containing a hydrogen fluoride gas.

### APPENDIX 2

In the etching method according to Appendix 1, the silicon-containing film may include a silicon oxide film, a silicon nitride film, a polysilicon film, or a laminated film including two or more types thereof.

### APPENDIX 3

In the etching method according to Appendix 1 or 2, the mask may include a silicon-containing film different from the silicon-containing film, or a carbon-containing film or a metal-containing film.

### APPENDIX 4

In the etching method according to Appendix 1 or 2, the mask may include an amorphous carbon film or a spin-on carbon film.

### APPENDIX 5

In the etching method according to Appendix 1 or 2, the mask may include a film including at least one type of metal selected from the group including tungsten, molybdenum, titanium, and ruthenium, or an oxide film, a nitride film, or a carbon film including the at least one type of metal.

### APPENDIX 6

In the etching method according to any one of Appendices 1 to 5, the (b) may include forming the metal-containing film from a second processing gas containing a metal-containing gas.

### APPENDIX 7

In the etching method according to Appendix 6, the metal-containing gas may include at least one type of metal selected from the group including tungsten, molybdenum, titanium, and ruthenium.

### APPENDIX 8

In the etching method according to Appendix 7, the metal-containing gas may include tungsten hexafluoride or molybdenum hexafluoride.

### APPENDIX 9

In the etching method according to any one of Appendices 6 to 8, the (b) may include forming the metal-containing film by generating plasma from the second processing gas.

### APPENDIX 10

In the etching method according to Appendix 1, the (b) may include forming the metal-containing film by causing the mask to adsorb a metal-containing precursor.

### APPENDIX 11

In the etching method according to Appendix 10, the (b) may include forming the metal-containing film by generating plasma from a gas that oxidizes or reduces at least a portion of the metal-containing precursor adsorbed by the mask.

### APPENDIX 12

In the etching method according to Appendix 11, in the (b), a portion of the metal-containing precursor adsorbed by the mask does not need to be oxidized or reduced.

### APPENDIX 13

In the etching method according to any one of Appendices 1 to 8, the (b) may include forming the metal-containing film by physical vapor deposition.

### APPENDIX 14

In the etching method according to Appendix 13, the (a) may include disposing the substrate on a substrate support, and the (b) may include forming the metal-containing film by sputtering a metal-containing electrode disposed to face the substrate support.

### APPENDIX 15

In the etching method according to any one of Appendices 1 to 9, the first processing gas may further include a phosphorus-containing gas.

### APPENDIX 16

In the etching method according to Appendix 15, the phosphorus-containing gas may include phosphorus halide or phosphorus chloride.

### APPENDIX 17

In the etching method according to any one of Appendices 1 to 9, the first processing gas may include a carbon-containing gas.

### APPENDIX 18

In the etching method according to any one of Appendices 1 to 9, the first processing gas may further include a halogen-containing gas.

### APPENDIX 19

In the etching method according to any one of Appendices 1 to 9, the first processing gas may include at least one type of gas selected from the group including an oxygen-containing gas, a boron-containing gas, and a metal-containing gas.

### APPENDIX 20

In the etching method according to any one of Appendices 1 to 9, a flow rate of the hydrogen fluoride gas is highest in the first processing gas.

### APPENDIX 21

In the etching method according to any one of Appendices 1 to 20, in the (b), a temperature of the substrate support that supports the substrate is set to a first temperature, and in the (c), the temperature of the substrate support is set to a second temperature lower than the first temperature.

### APPENDIX 22

In the etching method according to Appendix 21, the first temperature may be 0° C. or higher, and the second temperature may be lower than 0° C.

### APPENDIX 23

In the etching method according to any one of Appendices 1 to 22, a cycle including the (b) and the (c) may be repeated multiple times.

### APPENDIX 24

An etching method includes (a) preparing a substrate including a silicon-containing film and a mask on the silicon-containing film, the mask including an opening pattern, (b) forming a metal-containing film on the mask, and (c) etching the silicon-containing film by generating plasma from a first processing gas.

### APPENDIX 25

In the etching method according to Appendix 24, the first processing gas may include one or more gases from which plasma including a hydrogen fluoride species is generated when the plasma is generated from the first processing gas.

### APPENDIX 26

A plasma processing apparatus including a chamber and a controller, the controller being configured to perform
(a) control for preparing a substrate including a silicon-containing film and a mask on the silicon-containing film in the chamber, the mask including an opening pattern,
(b) control for forming a metal-containing film on the mask, and
(c) control for etching the silicon-containing film by generating plasma from a first processing gas containing a hydrogen fluoride gas.

The respective embodiments described above have been described for illustration, and are not intended to limit the scope of the present disclosure. Various modifications may be made to the respective embodiments of the present disclosure without departing from the scope and gist of the present disclosure. For example, some components in one embodiment may be added to another embodiment. Some components in an embodiment may be replaced with corresponding components in another embodiment.

1. An etching method comprising:
step (a) providing a substrate including a silicon-containing film and a mask on the silicon-containing film, the mask including an opening pattern;
step (b) forming a metal-containing film on the mask; and
step (c) etching the silicon-containing film by generating plasma from a first processing gas containing a hydrogen fluoride gas.

2. The etching method according to claim 1, wherein the silicon-containing film includes a silicon oxide film, a silicon nitride film, a polysilicon film, or a laminated film including two or more types of the silicon oxide film, the silicon nitride film and the polysilicon film.

3. The etching method according to claim 1, wherein the mask includes a silicon-containing film different from the silicon-containing film, a carbon-containing film or a metal-containing film.

4. The etching method according to claim 1, wherein the mask includes an amorphous carbon film or a spin-on carbon film.

5. The etching method according to claim 1, wherein the mask includes a film including at least one type of metal selected from the group including tungsten, molybdenum, titanium, and ruthenium, or
wherein the mask includes an oxide film, a nitride film, or a carbon film including the at least one type of metal.

6. The etching method according to claim 1, wherein step (b) includes forming the metal-containing film from a second processing gas containing a metal-containing gas.

7. The etching method according to claim 6, wherein the metal-containing gas includes at least one type of metal selected from the group including tungsten, molybdenum, titanium, and ruthenium.

8. The etching method according to claim 7, wherein the metal-containing gas includes tungsten hexafluoride or molybdenum hexafluoride.

9. The etching method according to claim 6, wherein step (b) includes forming the metal-containing film by generating plasma from the second processing gas.

10. The etching method according to claim 1, wherein step (b) includes forming the metal-containing film by causing the mask to adsorb a metal-containing precursor.

11. The etching method according to claim 10, wherein step (b) includes forming the metal-containing film by generating plasma from a second processing gas that oxidizes or reduces at least a portion of the metal-containing precursor adsorbed by the mask.

12. The etching method according to claim 11, wherein in step (b), a portion of the metal-containing precursor adsorbed by the mask is not oxidized or reduced.

13. The etching method according to claim 1, wherein step (b) includes forming the metal-containing film by physical vapor deposition (PVD).

14. The etching method according to claim 13, wherein step (a) includes disposing the substrate on a substrate support, and
step (b) includes forming the metal-containing film by sputtering a metal-containing electrode disposed to face the substrate support.

15. The etching method according to claim 1, wherein the first processing gas further includes a phosphorus-containing gas.

16. The etching method according to claim 15, wherein the phosphorus-containing gas includes phosphorus halide or phosphorus chloride.

17. The etching method according to claim 1, wherein the first processing gas includes a carbon-containing gas.

18. The etching method according to claim 1, wherein the first processing gas further includes a halogen-containing gas.

19. The etching method according to claim 1, wherein the first processing gas includes at least one type of gas selected from the group including an oxygen-containing gas, a boron-containing gas, and a metal-containing gas.

20. The etching method according to claim 1, wherein the first processing gas includes hydrogen fluoride, and
wherein a flow rate of the hydrogen fluoride gas is highest among gasses present in the first processing gas.

21. The etching method according to claim 1, wherein in step (b), a temperature of the substrate support that supports the substrate is set to a first temperature, and
in step (c), the temperature of the substrate support is set to a second temperature that is lower than the first temperature.

22. The etching method according to claim 21, wherein the first temperature is 0° C. or higher, and the second temperature is lower than 0° C.

23. The etching method according to claim 1, wherein a cycle including step (b) and step (c) is repeated multiple times.

24. An etching method comprising:
step (a) preparing a substrate including a silicon-containing film and a mask on the silicon-containing film, the mask including an opening pattern;
step (b) forming a metal-containing film on the mask; and
step (c) etching the silicon-containing film by generating plasma from a first processing gas.

25. The etching method according to claim 24, wherein the first processing gas includes one or more gases that generate a hydrogen fluoride species.

26. A plasma processing apparatus comprising:
a power source;
a chamber including an electrostatic chuck;
a temperature controller;
a gas introducer including a shower head; and
circuitry configured to:
control at least the temperature controller to prepare a substrate including a silicon-containing film and a mask on the silicon-containing film in the chamber, the mask including an opening pattern,
control at least the gas introducer to form a metal-containing film on the mask, and
control at least the power source, the gas introducer and the electrostatic chuck to etch the silicon-containing film by generating plasma from a first processing gas containing a hydrogen fluoride gas.
